(19) United States
(12) Patent Application Publication
(10) Pub. No.: US 2003/0119328 A1
(43) Pub. Date: Jun. 26, 2003

(54) Plasma processing apparatus, and cleaning method therefor

(75) Inventor: Toshiaki Fujisato, Nirasaki City (JP)

Correspondence Address: CROWELL & MORING LLP, INTELLECTUAL PROPERTY GROUP, P.O. BOX 14300, WASHINGTON, DC, 20044-4300, US

(73) Assignee: Tokyo Electron Limited, Tokyo (JP)

(21) Appl. No.: 10/328,049

(22) Filed: Dec. 26, 2002

(30) Foreign Application Priority Data
Dec. 26, 2001 (JP) 2001-394282

(51) Int. Cl. H01L 21/302; H01L 21/461

(52) U.S. Cl. 438/709; 438/710

(57) ABSTRACT

There is provided a gas exhaustion pipe which is directly connected to a diffusion member which diffuses a process gas and is formed inside an upper electrode which serves as a shower head. A cleaning gas exhaustion line whose one end is constituted by the gas exhaustion pipe is connected to a gas exhaustion line which is connected to a gas exhaustion port and exhausts gas inside a chamber. A cleaning gas supplied from a cleaning gas line is exhausted from the chamber through the inside of the upper electrode.

### BACKCGROUND OF THE INVENTION

1. Field of the Invention

The present invention relates to a plasma processing apparatus which applies a predetermined process to a process target using plasma, and a cleaning method for the plasma processing apparatus.

2. Description of the Related Art

When manufacturing electronic devices such as semiconductor devices, liquid crystal display devices, etc., plasma processing apparatuses are used for applying various processes such as an etching process and a chemical vapor deposition (CVD) process using plasma to a process target such as a semiconductor wafer. Among such plasma processing apparatuses, a plasma CVD apparatus is widely used in manufacturing electronic devices, because it is capable of forming a high-quality film.

The plasma CVD apparatus deposits a process gas which is turned into plasma on the surface of a process target such as a semiconductor wafer which is loaded in a chamber, and forms a film on the process target in accordance with a plasma CVD method. However, in accordance with this film forming method, the process gas etc., are deposited not only on the surface of the process target, but also inside the chamber (for example, on the surface of the internal wall), thus leaving depositions of the process gas thereinside. The depositions left inside the chamber turn into particles, and cause the yield of electronic devices lower. Therefore, it is required to clean regularly the inside the chamber to remove depositions.

As a method of cleaning the inside of the chamber, a so-called remote plasma cleaning method is known, wherein plasma of a cleaning gas is generated outside the chamber, and the generated plasma is introduced inside the chamber thereby to clean thereinside.

The remote plasma cleaning will now be explained with reference to a diagram. FIG. 12 is a schematic diagram of a parallel-plate plasma CVD apparatus 101, which can perform cleaning in accordance with the remote plasma cleaning.

As shown in FOGY 12, the plasma CVD apparatus 101 comprises a chamber 102, a susceptor 103 on which a process target W is set and which serves as a lower electrode, a pump 104 which can vacuum inside the chamber 102, and a shower head 106 which supplies a process gas all over the surface of the process target W through a plurality of minute gas holes 105 and which serves as an upper electrode. A fine diffusion path 107 is formed inside the shower head 106 in order to diffuse a process gas into the plurality of gas holes 105.

In the film forming step, in a state where a process gas is supplied between the susceptor 103 and the shower head 106, high-frequency electricity is applied to the upper electrode and the lower electrode to generate plasma. A film is formed on the surface of the process target W by the plasma generated from the process gas.

A cleaning gas line 108 is connected to the plasma CVD) apparatus 101. The cleaning gas line 108 comprises a cleaning gas source 109 and a plasma generator 110. A fluoride gas supplied from the cleaning gas source 109 is tamed into plasma in the plasma generator 110.

In the cleaning step, the plasma of the cleaning gas or fluorine radicals in the plasma is/are introduced through the cleaning gas line 108 into the chamber 102 via gas inlets 111 provided on the side walls of the chamber 102. Depositions inside the chamber 102 are etched and removed especially by the fluorine radicals in the introduced plasma.

The gas holes 105 and the diffusion path 107 of the shower head 106 serve as paths of the process gas. Since the gas holes 105 and the diffusion path 107 are finely formed, they are liable to formation of depositions. However, the cleaning gas can not easily enter the minute gas holes 105 and diffusion path 107. For this reason, it takes a long time to clean them sufficiently If cleaning takes a long time, that is, cleaning of the shower head 106 takes a long time, not only the throughput is lowered, but also other chamber elements are deteriorated due to excessive cleaning. On the other hand, if the cleaning time is short the shower head 106 can not be sufficiently cleaned and particles are increased, thus the throughput is lowered.

As described above, the conventional plasma CVD apparatus capable of remote plasma cleaning can not clean the shower head 106 easily. Accordingly, cleaning of the shower head 106 takes a long time, and efficient cleaning can not be carried out.

A lid 112 having slits is provided to each gas inlet 111, and the cleaning gas is introduced into the chamber 102 through the slits of the lid 112. This is to make the wall of the chamber 112 as flat as possible by covering the gas inlet 111 with the lid 112. If the wall of the chamber 102 is not flat, plasma generation becomes unstable, and abnormal discharge may easily occur. By providing the lid 112, occurrence of abnormal discharge around the gas inlet 111 can be reduced. However, when the cleaning gas is introduced into the chamber 102 through the slits of the lid 112, there is caused a loss of radicals which is the cleaning activator. Due to this, activity of the cleaning gas is lowered, ad the cleaning speed is lowered.

As described above, by providing the lid 112 to the conventional plasma CVD apparatus 101 capable of remote plasma cleaning, activity of the plasma of the cleaning gas is wasted, and thus activity of the cleaning gas can not be fully utilized. Accordingly, efficient cleaning can not be carried out.

The cleaning gas is supplied into the chamber 102 through the slits of the lid 112. Due to this, cleaning gas flows passing through adjacent slits tend to interfere with each other. This interference lowers the speed of supplying the cleaning gas. Accordingly, it is difficult for the cleaning gas to enter the shower head 106, and this lowers the cleaning speed.

As described above, the conventional plasma CVD apparatus capable of remote plasma cleaning has a problem that the speed of supplying the cleaning gas is lowered, and thereby the cleaning speed is lowered. Accordingly, there arises a problem that efficient cleaning is hardly performed.

### SUMMARY OF THE INVENTION

In view of the above circumstances, an object of the present invention is to provide a plasma processing apparatus which can be cleaned efficiently, and a cleaning method therefor.

Another object of the present invention is to provide a plasma processing apparatus which can be cleaned easily, and a cleaning method therefor.

Still another object of the present invention is to provide a plasma processing apparatus wherein activity of plasma of a cleaning gas is not easily wasted, and a cleaning method therefor.

Yet another object of the present invention is to provide a plasma processing apparatus which can prevent lowering of the cleaning speed, and a cleaning method therefor.

To achieve the above objects, a plasma processing apparatus according to a first aspect of the present invention comprises:

a chamber;

a process gas line which supplies a predetermined process gas into the chamber,

a diffusion electrode to which high frequency electricity can be applied, and which includes: a diffusion path which is connected to the process gas line for diffusing the process gas introduced through the process gas line; and a plurality of gas holes which are connected to the diffusion path for supplying the process gas diffused by the diffusion path into the chamber;

a cleaning gas line which supplies a cleaning gas for cleaning the inside of the chamber into the chamber; and

a cleaning gas exhaustion line one end of which is connected to at least one of the process gas line and the diffusion path, the other end of which is connected to a gas exhaustion mechanism, and which exhausts the cleaning gas in the chamber.

In this structure, the plasma processing apparatus may further comprise a process gas exhaustion line which exhausts the process gas introduced into the chamber through the process gas line, and the process gas exhaustion line may exhaust the process gas in the chamber via the gas exhaustion mechanism.

In this structure, the chamber may comprise a gas exhaustion port, the process gas exhaustion line may comprise a valve which is provided between the gas exhaustion mechanism and the gas exhaustion port, the other end of the cleaning gas exhaustion line may be connected between the valve of the process gas exhaustion line and the gas exhaustion mechanism, and the gas exhaustion mechanism may exhaust the cleaning gas in the chamber through the cleaning gas exhaustion line while the valve is closed.

In this structure, the cleaning gas line may comprise a gas activation mechanism, and supply the cleaning gas which is activated by the gas activation mechanism into the chamber.

In this structure, the gas activation mechanism may generate plasma of the cleaning gas.

To achieve the above objects, a plasma processing apparatus according to a second aspect of the present invention comprises:

a chamber;

a cleaning gas line which supplies a cleaning gas for cleaning the inside of the chamber into the chamber;

a cleaning gas inlet port which has an opening communicated with the inside of the chamber, and is connected to the cleaning gas line, the cleaning gas being introduced into the chamber through the opening; and

an opening and closing member which can open or close the cleaning gas inlet port.

In this structure, the plasma processing apparatus may further comprise a cleaning gas inlet path which is connected to the cleaning gas line and the cleaning gas inlet port, and introduces the cleaning gas from the cleaning gas line to the opening of the cleaning gas inlet port, and the opening and closing member may open or close the cleaning gas inlet port by opening or closing a route communicating the cleaning gas inlet path and the opening.

In this structure, the opening and closing member may comprise a lid which can be fit into the opening, a supporting member which supports the lid, and a driving mechanism which is connected to the supporting member for driving the lid to move back and forth.

In this structure, a surface of the lid which is exposed in the chamber and an internal surface of the chamber may constitute an almost same plane, when the lid is fit into the opening.

In this structure, the lid may be set at a same electric potential as that of the chamber.

In this structure, the lid may comprise a sealing member; and the sealing member may seal between the chamber and the lid airtightly, when the lid is fit into the opening.

In this structure, the cleaning gas line may comprise a gas activation mechanism, and supply the cleaning gas which is activated by the gas activation mechanism into the chamber.

In this structure, the gas activation mechanism may generate plasma of the cleaning gas.

To achieve the above objects, a plasma processing apparatus according to a third aspect of the present invention comprises: a chamber; a cleaning gas line which supplies a cleaning gas for cleaning the inside of the chamber; and a cleaning gas inlet port which is provided to the chamber for introducing the cleaning gas supplied from the cleaning gas line into the chamber,

wherein:

the cleaning gas inlet port is provided with a lid having a plurality of openings, and introduces the cleaning gas supplied from the cleaning gas line into, the chamber through the plurality of openings; and

the plurality of openings are formed so that cleaning gas flows which pass through the respective openings may not interfere with each other.

In his structure, the cleaning gas fine may comprise a gas activation mechanism, and supply the cleaning gas which is activated by the gas activation mechanism into the chamber.

In this structure, the gas activation mechanism may generate plasma of the cleaning gas.

To achieve the above objects, a method of cleaning a plasma processing apparatus according to a fourth aspect of the present invention is a method of cleaning a plasma processing apparatus which comprises: a chamber; a process gas line which supplies a predetermined process gas into the chamber; and a diffusion electrode to which high frequency electricity can be applied, and which includes a diffusion path which is connected to the process gas line for diffusing the process gas introduced through the process gas line and a plurality of gas holes which are connected to the diffusion path for supplying the process gas diffused by the diffusion path into the chamber, the method comprising:

an introducing step of introducing a cleaning gas into the chamber; and

a gas exhausting step of exhausting the cleaning gas introduced into the chamber out of the chamber through at least one of the process gas line and the diffusion path.

In this structure, the plasma processing apparatus may comprise a process gas exhaustion mechanism which exhausts the process gas introduced into the chamber from the process gas line, and in the gas exhausting step, the cleaning gas introduced into the chamber may be exhausted through the process gas exhaustion mechanism.

In this structure, the plasma processing apparatus may comprise a valve which is provided between the process gas exhaustion mechanism and a gas exhaustion port of the chamber, and a cleaning gas exhaustion line which is connected to a gas exhaustion side of the valve and exhausts the cleaning gas in the chamber, and in the gas exhausting step, the cleaning gas in the chamber may be exhausted through the cleaning gas exhaustion line with the valve closed.

In this structure, the introducing step may include an activating step of activating the cleaning gas.

In this structure, plasma of the cleaning gas may be generated in the activating step.

To achieve the above objects, a method of cleaning a plasma processing apparatus according to a fifth aspect of the present invention is a method of cleaning a plasma processing apparatus which comprises: a chamber, a cleaning gas line which supplies a cleaning gas for cleaning the inside of the chamber into the chamber; a cleaning gas inlet port which has an opening communicated with the inside of the chamber, and is connected to the cleaning gas line, the cleaning gas being introduced into the chamber through the opening; and an opening and closing member which can open or close the cleaning gas inlet port,

wherein plasma processing is performed while the cleaning gas inlet port is closed by the opening and closing member, and cleaning is performed while the cleaning gas inlet port is opened by the opening and closing member.

### BRIEF DESCRIPTION OF THE DRAWINGS

These objects and other objects and advantages of the present invention will become more apparent upon reading of the following detailed description and the accompanying drawings in which:

FIG. 1 is a diagram showing a structure of a plasma processing apparatus according to a first embodiment of the present invention;

FIG. 2 is a diagram showing a cross section of the plasma processing apparatus shown in FIG. 1;

FIG. 3 is a diagram showing a cross section of a chamber shown in FIG. 2;

FIG. 4 is a diagram showing a lid of FIG. 3;

FIG. 5 is a diagram showing a structure of a valve according to a second embodiment of the present invention;

FIG. 6 is a diagram showing a structure of the valve according to the second embodiment of the present invention;

FIG. 7 is a diagram showing a cross section of a chamber according to a third embodiment of the present invention;

FIG. 8 is a diagram showing a lid of FIG. 7;

FIGS. 9A and 9B are diagrams for explaining flow rate distributions;

FIGS 10A and 10B are diagrams for explaining changes of flow rates;

FIG. 11 is a diagram showing a structure of a lid according to another embodiment of the present invention; and

FIG. 12 is a diagram showing a cross section of a conventional plasma CVD apparatus.

### DETAILED DESCRIPTION OF THE PREFERRED EMBODIMENTS

First Embodiment

A plasma processing apparatus according to an embodiment of the present invention will now be explained with reference to the drawings. In the present embodiment, a so-called parallel-plate plasma CVD (Chemical Vapor Deposition) apparatus will be employed as a plasma processing apparatus. Further, in the present embodiment, a case where this plasma processing apparatus forms a silicon oxide fluoride (SiOF) film on a semiconductor wafer (hereinafter referred to as wafer W) by a film forming process and cleans during the film forming process with the use of plasma of nitrogen trifluoride (NF.sub.3) by a cleaning process, will be explained.

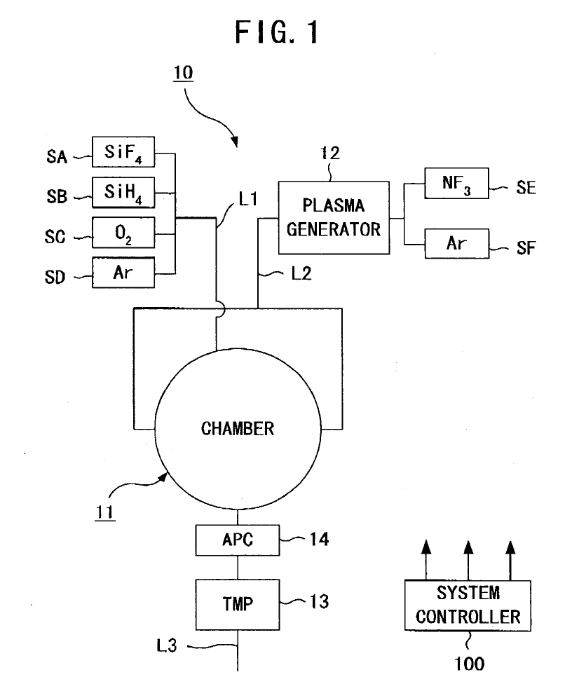

FIG. 1 shows the structure of the plasma processing apparatus 10 according to the present embodiment.

As shown in FIG. 1, the plasma processing apparatus 10 comprises a chamber 11, a process gas line L1, a cleaning gas line L2, a gas exhaustion line L3, and a system controller 100.

The chamber 11 is a reactor whose pressure can be reduced to a vacuum level. As will be described later, a plasma CVD process is performed inside the chamber 11, thereby a SiOF film is formed on the surface of a wafer W.

The process gas line L1 supplies a process gas into the chamber 11. The process gas consists of silane tetrafluoride (SiF.sub.4), silane (SiH.sub.4), and oxygen (O.sub.2) plus argon (Ar) as a carrier gas. The process gas line L1 connects a SiF.sub.4 source SA, a SiH.sub.4 source SB, a O.sub.2 source SC and a Ar source SD to the chamber 11. The SiF.sub.4 source SA, the SiH.sub.4 source SB, the O.sub.2 source SC, and the Ar source SD are connected to the chamber 11 via massflow controllers (not illustrated) respectively. Lines that connect the SiF.sub.4 source SA, the SiH.sub.4 source SB, the O.sub.2 source SC and the Ar source SD to the chamber 11 are gathered together into one line. SiF.sub.4, SiH.sub.4, O.sub.2, and Ar are mixed with a predetermined ratio, and supplied to the chamber 11. The process gas supplied into the chamber 11 is turned into plasma in the chamber 11 and deposited on the surface of the wafer W, thereby a SiOF film is formed on the surface of the wafer W.

The cleaning gas line L2 supplies a cleaning gas into the chamber 11. The cleaning gas consists of NF.sub.3 and Ar as a carrier gas. The cleaning gas line L2 connects a NF.sub.3 source SE and a Ar source SF to the chamber 11. The NF.sub.3 source SE and the Ar source SF are connected to the chamber 11 via massflow controllers (not illustrated) respectively. Lines that connect the NF.sub.3 source SE and the Ar source SF to the chamber 11 are once gathered together, and again branched into two to be connected to the chamber 11 separately. Accordingly, NF.sub.3 and Ar are mixed with a predetermined ratio and supplied into the chamber 11 through two channels.

The cleaning gas line L2 is provided with a plasma generator 12. The plasma generator 12 is arranged at the point where the first two separate lines of the cleaning gas line 12 get together. The plasma generator 12 has a plasma generation mechanism thereinside in order to generate plasma of the supplied gases (NF.sub.3 and Ar). The plasma generator 12 selectively emits mainly fluorine radicals in the generated plasma. Therefore, the cleaning gas whose main elements are fluorine radicals is supplied into the chamber 11 which is arranged at the downstream of the plasma generator 12.

A turbo molecule pump (TMP) 13 is connected to the gas exhaustion line L3. A dry pump (not illustrated) is arranged at the downstream of the turbo molecule pump 13, so that the inside pressure of the chamber 11 can be reduced to a vacuum level. An automatic pressure controller (APC) 14 is arranged between the turbo molecule pump 13 and the chamber 11. The inside pressure of the chamber 11 is set to a predetermined level by this automatic pressure controller 14.

The system controller 100 has control on the overall workings of the plasma processing apparatus 10 including the film forming process and cleaning process. The system controller 100 comprises a timer, for example, a software timer.

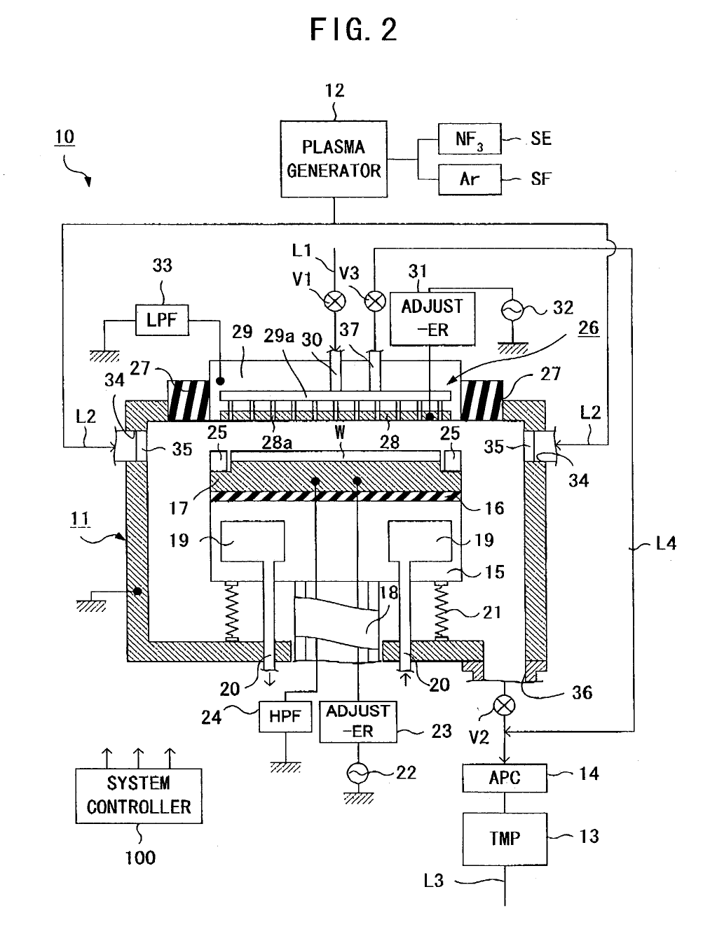

FIG. 2 is a cross section of the chamber 11 of the plasma processing apparatus IO shown in FIG. 1. In FIG. 2, the respective gas sources connected to the process gas line L1 are not illustrated in order to facilitate understanding of the present invention.

The chamber 11 has an almost cylindrical shape. The chamber 11 is made of, for example, aluminum whose surface has been anodized. The chamber 11 is grounded. A gate (not illustrated) is provided at the side wall of the chamber 11 to transport the wafer W in and out.

A circular-cylinder-like susceptor supporter 15 is provided at the bottom of the chamber 11 in the center. A susceptor 17 is provided on the susceptor supporter 15 via an insulator 16 such as ceramic. The susceptor supporter 15 is connected via a shaft 18 to an elevation mechanism (not illustrated) which is provided near the lower end of the chamber 11, so that the susceptor supporter 15 can be elevated or dropped together with the susceptor 17.

A refrigerant room 19 is provided inside the susceptor supporter 15, A refrigerant tube 20 is connected to the refrigerant room 19, and refrigerant is introduced into the refrigerant room 19 through the refrigerant tube 20. The refrigerant is controlled to be a predetermined temperature. The wafer W is kept at a desired temperature in consequence of the circulation of the refrigerant in the refrigerant room 19 and the conduction of the cold temperature of the circulating refrigerant via the susceptor 17.

The wafer W is kept at a desired temperature by the cool temperature of the refrigerant which is transmitted to the wafer W via the susceptor 17 when the refrigerant circulates in the refrigerant room 19.

The bottom of the susceptor supporter 15 is covered with bellows 21 made of stainless steel. The upper ends of the bellows 21 are fixed to the bottom surface of the susceptor supporter 15, and the lower end thereof are fixed to bottom of the chamber 11 by screws or the like The bellows 21 separate the normal pressure portion at the lower side of the susceptor supporter 15 from the vacuum portion inside the chamber 11. The bellows 21 expand or contract in accordance with elevation or drop of the susceptor supporter 15 in order to maintain airtightness inside the chamber 11 all the time.

The susceptor 17 has a disk-like protrusion on the top surface thereof at the center. An electrostatic chuck (not illustrated) having almost the same shape as the wafer W is provided on the disk-like protrusion. The susceptor 17 is a stand on which the wafer W is mounted. The wafer W mounted on the susceptor 17 is electrostatically adsorpted by Coulomb force.

The susceptor 17 serves as a lower electrode. A first high frequency power source 22 is connected to the susceptor 17. An adjuster 23 exists on the power supply line of the first high frequency power source 22 between the power source 22 and the susceptor 17. The first high frequency power source 22 has a frequency range of 0.1 to 13 MHz. By applying this frequency range, appropriate ionization effect can be given to the process target wafer W without causing any damage to the wafer W. The susceptor 17 is grounded via a high pass filter (EIPF) 24.

An annular focus ring 25 is arranged on the edge of the susceptor 17 around the disk-like protrusion so as to surround the wafer W mounted on the electrostatic chuck. The focus ring 25 is made of silicon, etc. The focus ring 25 effectively focuses plasma on the wafer W Set thereinside, thereby enables efficient and highly uniform plasma processing.

The susceptor supporter 15 and the susceptor 17, etc. together have a lift pin (not illustrated) which can penetrate to and from therebetween for passing the wafer W. The lift pin can move upward and downward by a cylinder, etc. The lift pin can move upward over the susceptor 17. The wafer W is mounted on the susceptor 17 by this upward and downward movement of the lift pin.

An upper electrode 26 is provided above the susceptor 17 so as to parallely face the susceptor 17. The upper electrode 26 is supported by the upper portion of the chamber 11 via an insulator 27. The upper electrode 26 comprises an electrode plate 28 and an electrode supporter 29.

The electrode plate 28 is fixed to the electrode supporter 29 with screws so as to face the susceptor 17 or the wafer W. A plurality of minute gas holes 28a are formed in the electrode plate 28 almost all over its surface. The electrode plate 28 is made of aluminum whose surface has been anodized, silicon, SiC, or amorphous carbon, etc. The electrode plate 28 and the susceptor 17 are arranged to have a distance of about 10 to 60 mm therebetween.

The electrode supporter 29 is made of a conductive material such as aluminum whose surface has been anodized, for example. The electrode supporter 29 comprises a refrigerant structure (not illustrated) thereinside. This refrigerant structure prevents overheat, etc. of the upper electrode 26.

A gas inlet pipe 30 is provided to the electrode supporter 29. The gas inlet pipe 30 constitutes a part of the process gas line L1. Therefore, the process gas is supplied into the chamber 11 through the process gas line L1 via the gas inlet pipe 30. A valve V1 is provided at the upstream of the gas inlet pipe 30.

The electrode supporter 29 comprises thereinside a hollow diffusion member 29a which is connected to the plurality of gas holes 28a of the electrode plate 28. The diffusion member 29a is patterned into a predetermined shape so as to have minute diffusion paths. The gas supplied through the gas inlet pipe 30 is diffused by the diffusion member 29a and supplied to the gas holes 28a. Thus, the process gas is supplied all over the wafer W uniformly from the plurality of gas holes 28a. As described above, the upper electrode 26 has a so-called shower head structure.

The upper electrode 26 is connected to a second high frequency power source 32 via a second adjuster 31. The second high frequency power source 32 applies frequencies within a range of 13 to 150 MHz, for example. By applying high frequency electricity (RF electricity), high-density plasma is generated between the upper electrode 26 and the susceptor 17 as the lower electrode The upper electrode 26 is grounded via a low pass filter (LPF) 33.

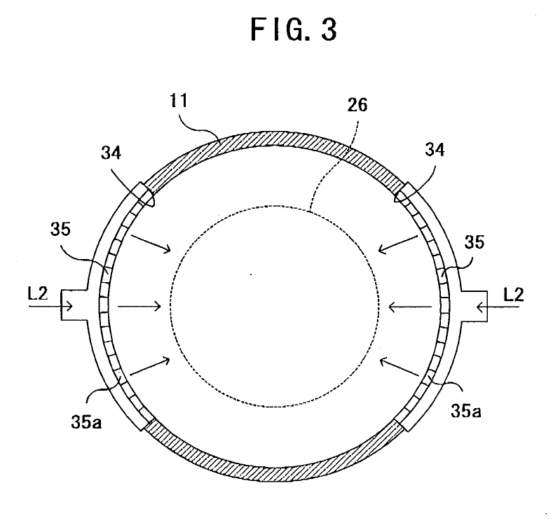

Cleaning gas inlet ports 34 are provided to the side walls of the chamber 1. There are two cleaning gas inlet ports 34, which are arranged to face each other as shown in FIG. 3. The cleaning gas inlet ports 34 are connected to the cleaning gas line L2. Therefore, the cleaning gas (plasma gas) supplied through the cleaning gas line L2 is supplied into the chamber 11 via the cleaning gas inlet ports 34.

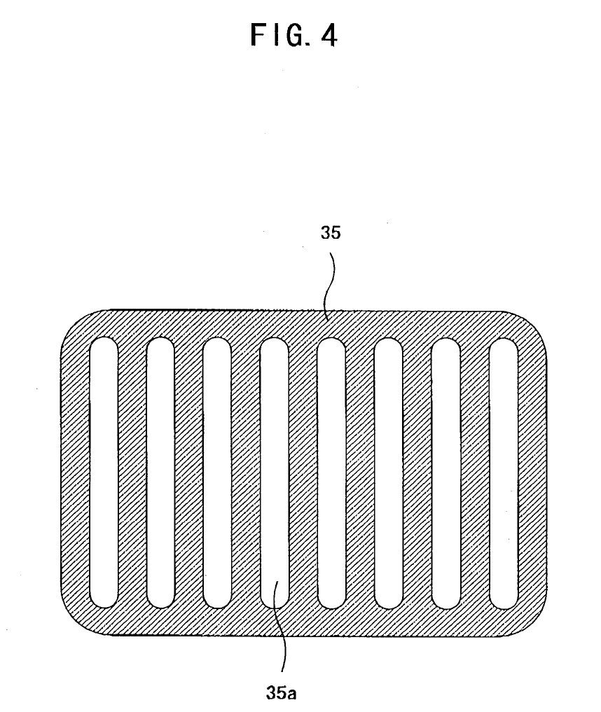

The cleaning gas inlet ports 34 are provided with lids 35 which have a plurality of slits 35a as shown in FIG. 4. The cleaning gas is introduced into the chamber 11 through the slits 35a. The lids 35 are made of the same material as that of the chamber 11 i.e., aluminum, for example. The lids 35 flatten the internal side walls of the chamber 11 in order to reduce occurrence of abnormal discharge when plasma is generated.

An gas exhaustion port 36 is provided at the bottom of the chamber 11. The gas exhaustion port 36 constitutes a part of the gas exhaustion line L3. As described above, the TMP 13 and the APC 14 are provided to the gas exhaustion line L3. Due to the workings of the TMP 13 and the APC 14, the chamber 11 is internally vacuumed to a predetermined pressure atmosphere, for example, to a pressure of 0.01 Pa or lower. And a valve V2 is provided between the gas exhaustion port 36 and the APC 14.

One end of a cleaning gas exhaustion line 1A is connected to gas exhaustion line L3 between the valve V2 and the APC 14. The other end of the cleaning gas exhaustion line L4 constitutes a gas exhaustion pipe 37 which is provided to the upper electrode 26. The gas exhaustion pipe 37 is connected to the diffusion member 29a inside the upper electrode 26 (electrode supporter 29). That is, one end of the cleaning gas exhaustion line L4 is connected to the diffusion paths (diffusion member 29a) inside the upper electrode 26, and the other end thereof is connected to the gas exhaustion line L3. A valve V3 is provided at the upstream of the gas exhaustion pipe 37. As will be described later, the cleaning gas exhaustion line L4 is prepared to clean the upper electrode 26 in particular.

Now, with reference to FIG. 2, the operation of the plasma processing apparatus 10 when performing the film forming process and the cleaning process (or the cleaning method of the plasma processing apparatus 10) will be explained. The operation to be described below is merely an example. Therefore, any other operation is acceptable as long as it achieves the same effect as this example. In the following explanation, workings of the elements constituting the plasma processing apparatus 10 are controlled by the system controller 100.

First, a wafer W is conveyed into the chamber 11 through the gate (not illustrated), and mounted on the susceptor 17. Then, the wafer W is electrostatically adsorpted to the susceptor 17 by the electrostatic chuck (not illustrated). Then, the internal pressure of the chamber 11 is set to a predetermined level by the automatic pressure controller 14. Refrigerant which is controlled to have a predetermined temperature is introduced into the refrigerant room 19 through the refrigerant tube 20 o as to circulate thereinside, in order to set the wafer W at a predetermined temperature. Successively, the O.sub.2 source SC starts supplying a predetermined amount of O.sub.2, and the second high frequency power source 32 is turned on to apply RF electricity to the upper electrode 26.

Next, the process gas controlled by the massflow controllers (not illustrated) to have a predetermined flow amount, i.e., SiF.sub.4, SiH.sub.4, O.sub.2, and Ar arc supplied into the gas inlet pipe 30 (chamber 11) from the SiF.sub.4 source SA, the SiH.sub.4 source SB, the O.sub.2 source SC, and the Ar source SD. The process gas supplied into the gas inlet pipe 30 is diffused when passing through the diffusion member 29a of the electrode supporter 29, and supplied all. over the electrode plate 28 uniformly. The process gas supplied to the electrode plate 28 is supplied to the surface of the wafer W uniformly through the gas holes 28a of the electrode plate 28. Then, the first high frequency power source 22 is turned on to apply electricity to the lower electrode (susceptor 17). Due to this, plasma of the process gas is generated and deposited on the, surface of the wafer W, forming a SiOF film on the surface of the wafer W.

When the SiOF film having a predetermined thickness is formed on the surface of the wafer W, the first high frequency power source 22 is turned off to stop applying RF electricity to the lower electrode (susceptor 17). Further, the SiF.sub.4 source SA, the SiH.sub.4 source SB and the Ar source SD stop supplying SiF.sub.4, SiH.sub.4, and Ar to the chamber 11. Afterwards, the electrostatic adsorption by the electrostatic chuck is stopped. Then, supply of O.sub.2 from the O.sub.2 source SC to the chamber 11 is stopped, and the second high frequency power source 32 is turned off to stop applying RF electricity to the upper electrode 26. Finally, the wafer W is transported out of the chamber 11 through the gate, and the film forming process is completed.

The cleaning process is performed when this film forming process is repeated for a predetermined number of wafers W, and thus depositions are accumulated in the chamber 11.

First, a dummy wafer W for cleaning is transported into the chamber 11 through the gate (not illustrated), and mounted on the susceptor 17. Then, the dummy wafer W is electrostatically adsoprted to the susceptor 17 by the electrostatic chuck (not illustrated).

Then, the valve V1 connected to the process gas line L1, and the valve V2 connected to the gas exhaustion line L3 are closed, and the valve V3 connected to the cleaning gas exhaustion line L4 is opened. Due to this, a gas supply and exhaustion system constituted by the cleaning gas line L2, the inside of the chamber 11, the cleaning gas exhaustion line L4, and the TMP 13 (gas exhaustion line L3) is formed.

Next, supply of the cleaning gas is started. That is, the NF.sub.3 source SE and the Ar source SF start supplying NF.sub.3 and Ar. And the plasma generator 12 is turned on. As a result, plasma of NF.sub.3 is generated from the cleaning gas supplied into the plasma generator 12. Then, fluorine radicals in the plasma are introduced into the chamber 11 through the cleaning gas inlet ports 34. The depositions (films made of SiOF, etc.) on the walls of the chamber 11, on the susceptor 17, etc., are decomposed and removed by the cleaning gas. The cleaning gas and the decomposed depositions are exhausted out of the chamber 11 through the gas exhaustion pipe 37, the cleaning gas exhaustion line L4, and the gas exhaustion line L3.

The gas holes 28a and diffusion member 29a of the upper electrode 26 catch depositions most easily of all the parts in the chamber 11, because the process gas is apt to stay there. Further, it has been difficult to supply the cleaning gas into the upper electrode 26, according to a conventional plasma processing apparatus.

In the plasma processing apparatus 10 of the present embodiment, the gas exhaustion pipe 37 is connected to the diffusion member 29a inside the electrode supporter 29. That is, the cleaning gas exhaustion line L4 is connected to the diffusion paths (diffusion member 29a) inside the upper electrode 26. And the valve V1 and the valve V2 are closed. Therefore, the cleaning gas introduced into the chamber 11 is exhausted to the outside of the chamber 11 through the gas holes 28a, the diffusion member 29a, the gas exhaustion pipe 37, the cleaning gas exhaustion line L4, and the gas exhaustion line L3. In this manner, the cleaning gas can be easily supplied to the inside of the upper electrode 26 (gas holes 28 and diffusion member 29a). And the depositions of the gas holes 28a and diffusion member 29a can be decomposed and removed by the supplied cleaning gas.

Accordingly, it is possible to clean the inside of the upper electrode 26 in which depositions are easily formed and to which the cleaning gas is difficult to supply, more quickly and sufficiently than a conventional plasma processing apparatus. Therefore, it is possible to carry out an efficient cleaning which requires a loss time. Further, deterioration of other elements in the chamber 11 can be reduced, and high yield and high throughput can be achieved.

During the above cleaning process, the system controller 100 monitors progresses of this process based on a predetermined completion detection method utilizing pressures, optical data, etc. When the system controller 100 detects a completion of the cleaning process, the plasma generator 12 is turned off, supply of the cleaning gas is stopped. Thereafter, predetermined amounts of O.sub.2 and Ar are supplied into the chamber 11 from the O.sub.2 source SC and the Ar source SF. Then, electrostatic chucking is stopped, and supply of O.sub.2 and Ar from the O.sub.2 source SC and the Ar source SF is stopped. Finally, the dummy wafer W is transported out of the chamber 117 and the cleaning process is finished.

As explained above, according to the present embodiment, the gas exhaust pipe 37 (cleaning gas exhaustion line L4) is provided so as to be connected to the diffusion member 29a inside the upper electrode 26 Because of this, the inside of the upper electrode 26 in which depositions are easily formed, and which is the most difficult to clean, can be easily cleaned. Accordingly, efficient cleaning can be carried out Further, this cleaning process realizes high yield and high throughput because it restricts deterioration of other chamber elements.

The present invention is not limited to the above embodiment, but can be variously modified and applied. Modifications of the above embodiment which can be applied to the present invention will now be explained below.

In the above embodiment, cleaning is carried out with the valve V2 connected to the gas exhaustion line L3 closed. However, cleaning may be carried out with the valve V2 opened. In this case, the cleaning gas introduced into the chamber 11 is exhausted from the gas exhaustion port 36 (gas exhaustion line L3) and the gas exhaustion pipe 37 (cleaning gas exhaustion line L4). Due to this, not only the upper electrode 26, but also the lower portion of the chamber 11 can be cleaned efficiently.

Further, cleaning with the use of only the gas exhaustion pipe 37 (cleaning gas exhaustion line L4), and cleaning with the use of the gas exhaustion port 36 (gas exhaustion line L3) and the gas exhaustion pipe 37 (cleaning gas exhaustion line L4) may be combined. For example, the system controller 100 may comprise a counter. Every time cleaning with the use of only the gas exhaustion pipe 37 (cleaning gas exhaustion line L4) is repeated several times, the combined cleaning with the use of the gas exhaustion port 36 (gas exhaustion line L3) and the gas exhaustion pipe 37 (cleaning gas exhaustion line L4) may be carried out.

In the above embodiment, the gas exhaustion pipe 37 is connected to the diffusion member 29a inside the upper electrode 26. That is, the cleaning gas exhaustion line L4 is connected to the diffusion member 29a inside the upper electrode 26. However, the position at which the gas exhaustion pipe 37 is provided is not limited to this. For example, the gas exhaustion pipe 37 may be provided as a pipe diverged from the gas inlet pipe 30 for introducing the process gas. In this case, the cleaning gas exhaustion line L4 may be connected to the gas exhaustion side of the valve V1. As above, the cleaning gas exhaustion line L4 may be connected to the process gas line L1. Further, the number of the gas exhaustion pipe 37 connected to the upper electrode 26 is not limited to one, but may be plural.

Second Embodiment

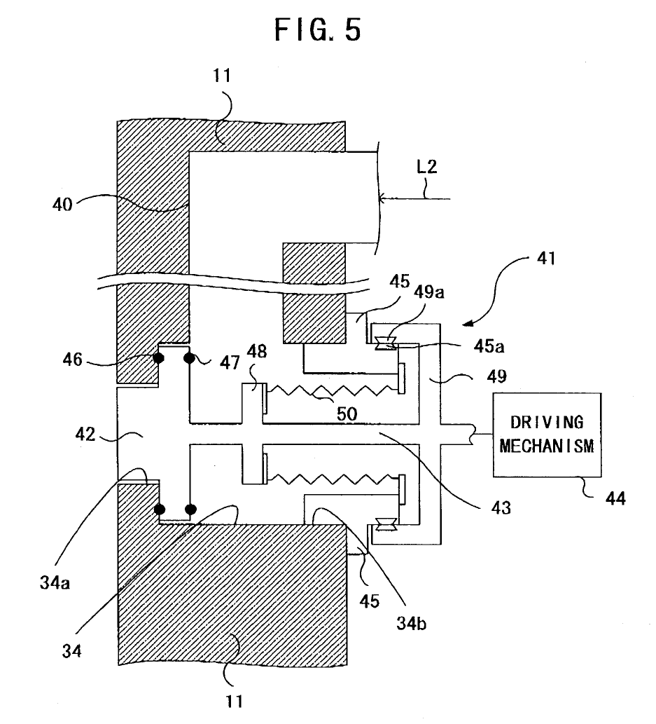

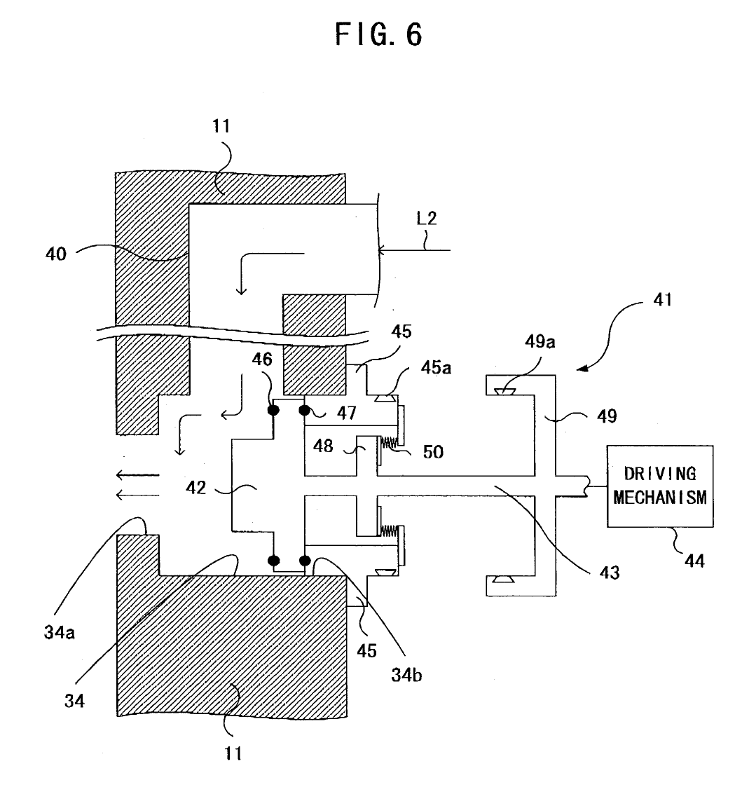

In the first embodiment the cleaning gas inlet ports 34 are provided with the lids 35 having the slits 35a, in order to reduce abnormal discharge. In the second embodiment, the cleaning gas inlet ports 34 are not provided with the lids 35, but with angle valve type valves of an angle valve type which can be opened and closed FIG. 5 and FIG. 6 show the structure around the cleaning gas inlet port 34 according to the present embodiment. FIG. 5 and FIG. 6 show the closed state and the opened state of the cleaning gas inlet port 34, respectively.

As shown in FIG. 5, the cleaning gas inlet port 34 is provided so as to penetrate the side wall of the chamber 11. The cleaning gas inlet port 34 comprises a first opening 34a at the inner side of the chamber 11, and a second opening 34b at the outer side of the chamber 11. The first opening 34a and the second opening 34b have different diameters from each other, and the diameter of the second opening 34b is larger than that of the first opening 34a. Thus, the cleaning gas inlet port 34 has a longitudinal difference thereinside.

A side tube 40 is embedded in the side wall of the chamber 11 near the cleaning gas inlet port 34 so as to be connected to the cleaning gas inlet port 34 almost perpendicularly. The side tube 40 is arranged almost in parallel with the side wall of the chamber 11. The side tube 40 is bent almost perpendicularly on the way, and sticks out of the side wall of the chamber 11 to be connected to the cleaning gas line L2 which is provided outside of the chamber 11. The side tube 40 is made of a material which is highly plasma-proof such as resin, metal, etc, or the same material as that of the chamber 11 instead of providing the side tube 40, a similar tubular hole may be formed in the side wall of the chamber 11.

A valve 41 is provided in the cleaning gas inlet port 34 so as to fill the second opening 34b. The valve 41 comprises a lid 42, a stem 43 for supporting the lid 42, a driving mechanism 44 connected to the stem 43, and a fixing member 45.

The lid 42 is made of the same material as that of the chamber 11, for example, aluminum. The lid 42 is formed into a disk-like shape having a protrusion. The area of the protrusion of the lid 42 is formed to be almost equal to the area of the first opening 34a, or slightly smaller than the area of the first opening 34a. The height of the protrusion of the lid 42 is formed to be almost equal to the depth of the first opening 34a. Therefore, the lid 42 has a shape fit to the first opening 34a and the longitudinal difference. That is, when the lid 42 is fit into the first opening 34a (when the cleaning gas inlet port 34 is closed), the principal surface of the protrusion constitutes the same surface as the nearby side wall (internal surface) of the chamber 11. The principal surface of the lid 42 including this protrusion is anodized.

A first O ring is provided to one surface of the lid 42 that has this protrusion, so as to surround the protrusion The first O ring 46 seals the first opening 34a airtightly, when the lid 42 is fit into the cleaning gas inlet port 34 as shown in FITG. 5. A second O ring 47 is provided to the other surface of the lid 42 so as to be opposed to the first O ring 46.

The stem 43 is made of the same material as that of the chamber 11, for example, aluminum, The lid 42 is provided to one end of the stem 43. The stem 43 is manufactured together with the lid 42 as one unit. The stem 43 has a disk-like bellows mount 48. A connector 49 is provided to the portion of the stem 43 that exists outside the chamber 11. The connector 49 is constituted by a hollow cylindrical member having a bottom surface. Therefore, the connector 49 has an L-shaped cross section. A plate-like contact unit 49a made of a general electrode material is provided On the internal wall of the cylindrical portion of the connector 49.

The driving mechanism 44 is connected to the other end of the stem 43. The driving mechanism 44 is driven by an air cylinder, a motor, etc. Due to this, the lid 42 and the stem 43 can move back and forth in the drawing direction with respect to the cleaning gas inlet port 34 (i.e., leftward and rightward in FIG. 5). The driving mechanism 44 is connected to the controller 100, and opens or closes the cleaning gas inlet port 34 in accordance with an instruction from the controller 100.

The fixing member 45 is made of the same material as that of the chamber 11, for example, aluminum. The fixing member 45 is constituted by a hollow cylindrical member having a portion protruding toward outside. The fixing member 45 is fit into the second opening 34b of the cleaning gas inlet port 34, and the portion protruding toward outside is fixed on the outer wall of the chamber 11 by screws, etc.

One end of the bellows 50 is fixed to a an end of the fixing member 45 that is not fit into the second opening 34b, and the other end of the bellows 50 is fixed on the bellows mount 48 of the stem 43. The bellows 50 are made of stainless steel or the like. The internal diameter of the cylindrical fixing member 45 is set to be larger than the diameter of the bellows mount 48 of the stem 43. Therefore, the stem 43 and the bellows mount 48 can move back and forth inside the fixing member 45 due to the driving mechanism 44.

The bellows 50 are arranged so as to cover the stem 43 from the bellows mount 48 of the stem 43 to the end of the fixing member 45. By providing the bellows 50, airtightness inside and outside the chamber 11 can be maintained when the lid 42 moves back and forth.

A plate-like contact unit 45a made of a general electrode material is provided on the outer circumference of an end portion of the fixing member 45 that is not fixed into the second opening 34b. The contact unit 45a of the fixing member 45 is arranged so as to contact the contact unit 49a of the connector 49 as shown in FIG. 5. When the cleaning gas inlet port 34 is closed, the whole valve 41 including the lid 42 is set at the same electric potential (ground potential) as the chamber 11. Accordingly, no unstable electric field is generated near the lid 42, and occurrence of abnormal discharge can be prevented.

As described above, the lid 42 can move back and forth in the drawing direction with respect to the cleaning gas inlet port 34 due to the driving mechanism 44. Due to this backward and forward movement, the valve 41 opens or closes the cleaning gas inlet port 34 (first opening 34a). More specifically, the lid 42 opens or closes the cleaning gas inlet port 34 by moving to and from between the first opening 34a and the side tube 40.

In the opened state of the cleaning gas inlet port 34 shown in FIG. 6, the lid 42 contacts an end of the fixing member 45 that is fit into the second opening 34b. In this state, the second O ring 47 seals between the lid 42 and the end of the fixing member 45 airtightly.

The cleaning gas is introduced into the chamber 11 through the cleaning gas line L2 via the side tube 40 and the first opening 34a. At this time, the cleaning gas is directly introduced into the chamber 11, not via the slits 35a of the first embodiment Therefore, a loss of radicals in the cleaning gas due to passing through the slits 35a can be prevented, and the activity of the cleaning gas, can be kept high. Accordingly, reduction in the cleaning speed can be prevented.

In the opened state of the cleaning gas inlet port 34, advancing of the fixing member 45 toward the inside by the cleaning gas can be prevented by the second O ring 47. Therefore, deterioration of the bellows 50 due to the cleaning gas can be prevented.

As described above, according to the present invention, it is possible to supply the cleaning gas into the chamber 11 without letting the gas pass through the slits 35a. Therefore, any loss of radicals in the cleaning gas can be prevented, the activity of the cleaning gas can be kept high, and thereby lowering of the cleaning speed can be prevented.

Further, since the lid 42 of the valve 41 is provided so as to form almost the same plane as the side wall (internal surface) of the chamber 11 in the state where the lid 42 is fit into the first opening 34a, it is possible to reduce occurrence of abnormal discharge when plasma processing is performed.

Therefore, efficient cleaning can be performed.

The structure of the valve 41 is not limited to the above described one, but any structure is possible as long as it can prevent abnormal discharge, and it can supply the cleaning gas into the chamber 11 while keeping it highly active.

According to the present embodiment, the side tube 40 is provided in the wall of the chamber 11. However, the side tube 40 may be provided outside of the chamber 11, and side tube 40 and the valve 41 may be connected to each other outside of the chamber 11.

Further, other scaling members than the O rings 46 and 47, such as a labyrinth seal may be employed.

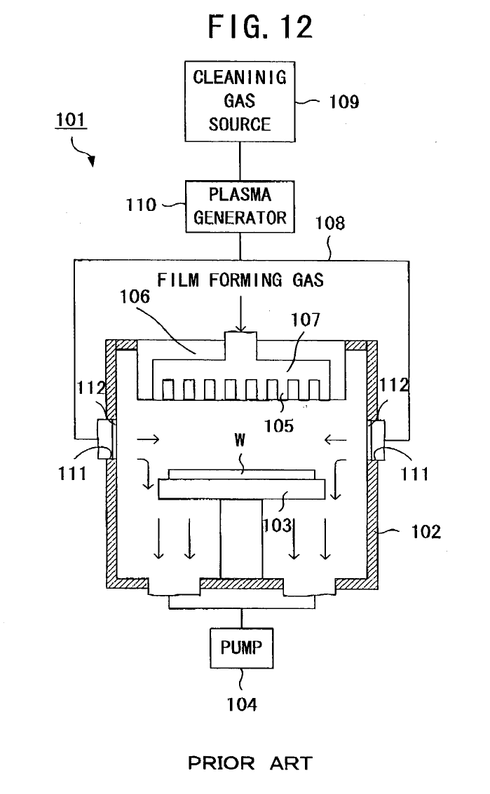

Further, in the present embodiment, there has been explained a case where the valve 41 etc., are provided to the cleaning gas inlet port 34 instead of the lids 35, in the plasma processing apparatus 10 according to the first embodiment where the gas exhaustion pipe 37 (cleaning gas exhaustion line L4) is provided to the diffusion member 29a inside the upper electrode 26. However, the present invention is not limited to this scheme. Therefore, the valve 41 and the like may be used in a plasma processing apparatus which has no gas exhaustion pipe 37 (cleaning gas exhaustion line 14), such as the plasma CVD apparatus 101 shown in FIG. 12, instead of using the lid 112 thereof. In this case, it is also possible to keep the activity of the cleaning gas high, and prevent reduction in the cleaning speed. Accordingly, efficient cleaning can be carried out.

Third Embodiment

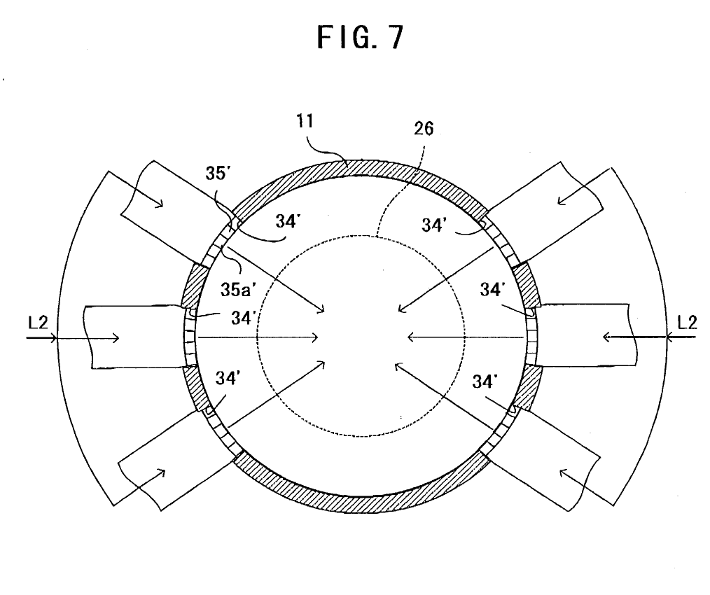

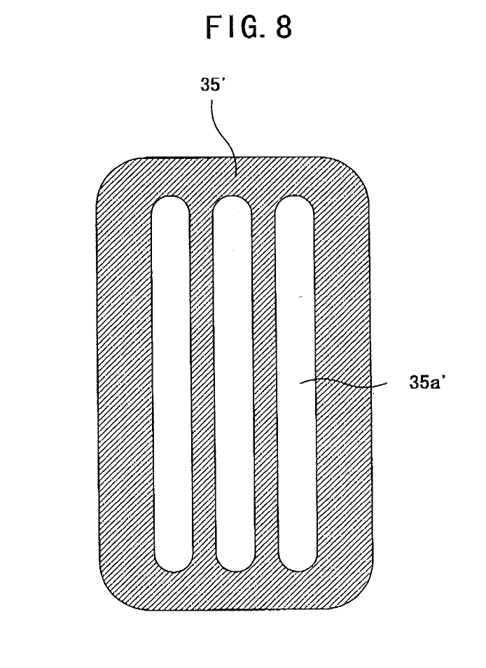

In the first embodiment, the chamber 11 has the two cleaning gas inlet ports 34 on its side walls so as to face each other as shown in FIG. 3, and each cleaning gas inlet port 34 has the lid 35 having the plurality of slits 35a as shown in FIG. 4. In the third embodiment, there are provided more than two cleaning gas inlet ports which have almost the same aperture area as that of the two cleaning gas inlet ports 34 of the first embodiment, and each cleaning gas inlet port comprises a lid having slits densely compared to the slits 35a of the first embodiment. The cleaning gas inlet ports according to the present embodiment are shown in FIG. 7, and the lids according to the present embodiment are shown in FIG. 8.

As shown in FIG. 7, the chamber 11 comprises three or more, for example, six cleaning gas inlet ports 34′ which are connected to the cleaning gas line 12. In the present embodiment, three cleaning gas inlet ports 34′ are provided on the side wall of the chamber 11 with predetermined intervals therebetween, and another three cleaning gas inlet ports 34′ are provided on the side wall of the chamber 11 so as to face them. The cleaning gas inlet ports 34′ are arranged at almost the same height as the cleaning gas inlet ports 34 (i.e., slightly higher than the susceptor 17).

The whole aperture area of the cleaning gas inlet ports 34′ (the total aperture area of the six cleaning gas inlet ports 34′) is designed to be almost the same as the whole aperture area of the cleaning gas inlet ports 34 of the first embodiment (the total of the aperture area of the two cleaning gas inlet ports 34). That is, the aperture area of each cleaning gas inlet port 34′ is designed to be one third of the aperture area of one cleaning gas inlet port 34 of the first embodiment.

Each cleaning gas inlet port 34′ has a lid 35′ as shown in FIG. 8. Therefore, the cleaning gas is supplied into the chamber 11. through the lid 35′.

The lid 35′ has a plurality of slits 35a′. Each slit 35a′ is formed into almost the same shape. as the slit 35a of the first embodiment. The slits 35a′ are provided to each lid 35′, such that the total number of the slits 35a′ provided to all of the lids 35′ is about the same as the total number of the slits 35a of the first embodiment. In the present embodiment, each lid 35′ has three slits 35a′. Further, the interval between the slits 35a′ of the lid 35′ is formed to be smaller than the interval between the slits 35a of the first embodiment. That is, the slits 35a′ are formed to the lid 35′ densely compared to those of the lid 35 of the first embodiment.

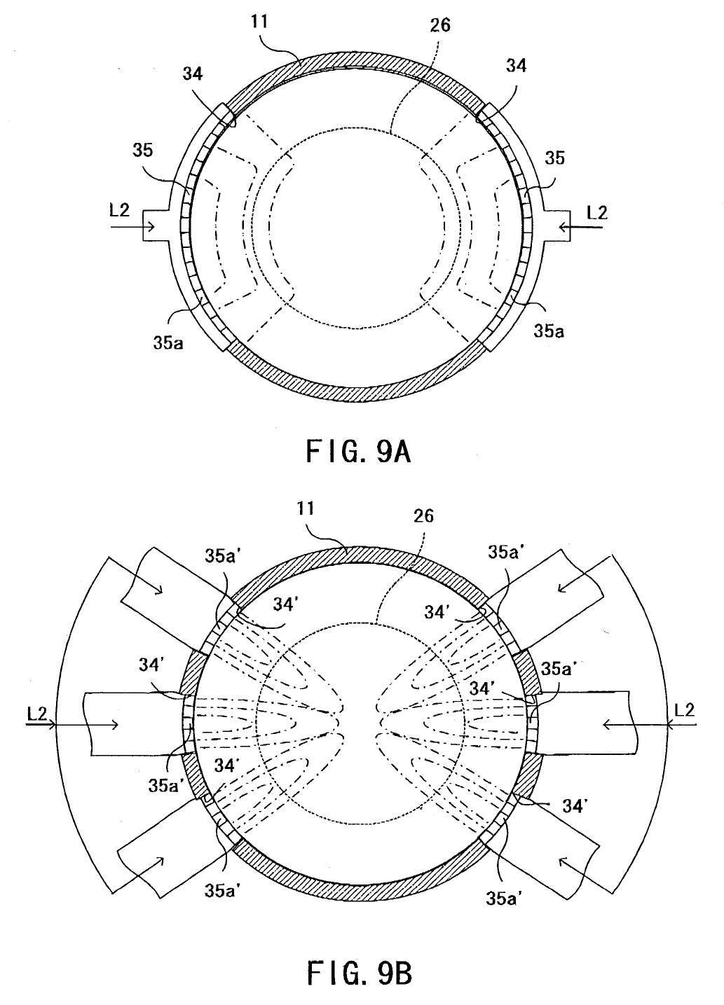

FIGS. 9A and 9B respectively show flow rate distributions of a case where the same flow amount of cleaning gas is introduced through the cleaning gas inlet ports 34, and the cleaning gas inlet ports 34′. FIG. 9A shows a flow rate distribution of a case where the chamber 11 has the two cleaning gas inlet ports 34, each of which has the lid 35 to which the slits 35a are provided relatively sparsely. FIG. 9B shows a flow rate distribution of a case where the chamber 11 has the six cleaning gas inlet ports 34′, each of which has the lid 35′ to which the slits 35a′ are provided relatively densely. Both FIGS. 9A and 9B show the flow rate distributions by chain lines in three stages, respectively. In FIGCS. 9A and 9B, each stage represents almost the same flow rate level.

As shown in FIG. 9A₇ the flow rate distribution of the cleaning gas which is introduced into the chamber 11 through the lids 35 having the relatively sparse slits 35a is relatively gentle all over the cleaning gas inlet ports 34. On the other hand, as shown in FIG. 9B, the flow rate distribution of the cleaning gas which is introduced into the chamber 11 through the lids 35′ having the relatively dense slits 35a′ is relatively steep, and the higher-rate areas reach the center of the chamber 11.

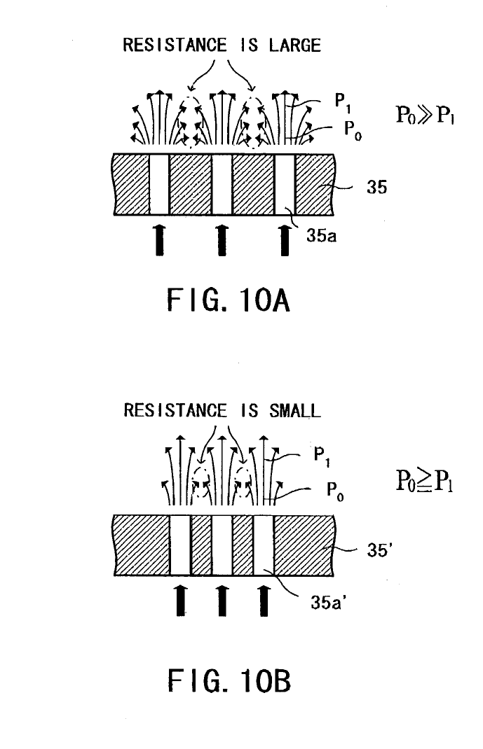

The reason why both the flow rate distributions differ is considered to be that the cleaning gas flows passing through adjacent slits resist (interfere with) each other differently in case of the slits 35a and in case of the slits 35a′. As shown in FIG. 10A, when the cleaning gas passing through the relatively sparse slits 35a diffuses, resistance (interference) caused by collision of diffused elements is relatively large On the other hand, as shown in FIG. 10B, when the cleaning gas passing through the relatively dense slits 35a′ diffuses, resistance (interference) caused by collision of diffused elements is relatively small.

Let the flow rate of the cleaning gas immediately after passing through the slits 35a or 35a′ be P₀, and the flow rate of the cleaning gas at a predetermined point after passing through the slits 35a or 35a′ be P₁. By the composition showing the relatively sparse slits 35a in FIG. 10A, P₁ decreases greatly than P₀, relatively (P₀>>P₁). On the other hand, the composition showing the relatively dense slits 35a′ in FIG. 10B, reduction of P₁ is relatively small (P₀≧P₁). Therefore, by providing slits relatively dense like the slits 35a′, interference between cleaning gas flows passing through adjacent slits 35a′ can be suppressed, and the cleaning gas supply speed at the center of the chamber 11 can be kept high.

As explained above, according to the present embodiment, by forming the slits 35a′ of the lids 35′ relatively densely, it is possible to restrict reduction in the flow rate due to interference between adjacent cleaning gas flows, and thereby to achieve a high cleaning gas supply speed even at the center of the chamber 11. Therefore, the cleaning gas can be easily sent into the upper electrode 26. Accordingly, it is possible to improve the cleaning speed inside the upper electrode 26, thereby efficient cleaning can be carried out.

In the above embodiment, there has been explained a case where the lids 35′ having the relatively dense slits 35a′ are provided to the cleaning gas inlet ports 34′, in the plasma processing apparatus 10 according to the first embodiment where the gas exhaustion pipe 37 (cleaning gas exhaustion line L4) is provided to the diffusion member 29a inside the upper electrode 26. However, the present invention is not limited to this. For example, the cleaning gas inlet ports 34′ may be provided to a plasma processing apparatus which does not have the gas exhaustion pipe 37 (cleaning gas exhaustion line L4), such as the plasma CVD apparatus 101 shown in FIG. 12, and the lids 35′ having the slits 35a′ may be provided to the cleaning gas inlet ports 34′ of such an apparatus. In this case too, it is possible to improve the cleaning speed. Accordingly, efficient cleaning can be carried out.

Further, in the above embodiment, a case where the chamber 11 has six cleaning gas inlet ports 34′ has been explained. However, according to the present embodiment, any case is acceptable if the slits of the lids provided to the cleaning gas inlet ports are formed relatively dense so that cleaning gas flows may not interfere with each other. For example, the cleaning gas inlet ports 34 of the first embodiment may be provided with lids having relatively dense slits. In this case, it is also possible to improve the cleaning speed. Accordingly, efficient cleaning can be carried out.

The present invention is not limited to the above described first to third embodiments, but can be variously modified and applied. For example, the cleaning gas inlet ports 34 may be inclined so that the cleaning gas passing through the cleaning gas inlet ports 34 can be supplied to the lower surface of the upper electrode 26 (electrode plate 28). Due to this, it becomes easier for the cleaning gas to get into the upper electrode 26, and thus, more efficient cleaning can be carried out. Further, the plurality of cleaning gas inlet ports 34 may not be arranged at the same height. For example, there may be a cleaning gas inlet port 34 that faces the upper electrode 26, or one that faces the susceptor 17.

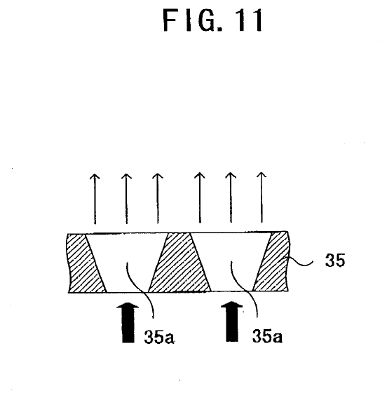

The number of cleaning gas inlet ports 34 is not limited to those in the above described embodiments, but may be arbitrary as long as efficient cleaning can be carried out. The shape and number of the slits 35a of the lids 35 are not limited to those in the above described embodiments, but may be arbitrary in accordance with the shape and number, etc. of the cleaning gas inlet port 34. Further, circular holes may be used instead of the slits 35a. Still further, the slits 35a of the lids 35 may be formed into a tapered shape, as shown in FIG. 11.

Needless to say, it is possible to achieve a higher cleaning gas supply speed, by adjusting the aperture area of the cleaning gas inlet ports 34, the number of the slits 35a provided to the lids 35, the aperture area of each slit 35a, a distance with respect to flowing directions of the slits 35a (thickness of the lids 35), etc.

In the above embodiments, the cleaning gas is activated so as to generate plasma, especially, radicals in the plasma. However, by activating the cleaning gas, activators other than radicals may be generated for cleaning.

In the above embodiments, an SiOF film is formed on a wafer W in a parallel-plate plasma CVD apparatus, and cleaning gas is performed using NF.sub.3 gas. However, the film to be formed is not limited to the SiOF film, bat may be a silicon film such as SiO.sub.2, SiC, SiN, SiCN, SiCH, SiOCH, etc. Further, not only NF.sub.3, but also fluorine gas such as CF.sub.4, C.sub.2F.sub.6, SF.sub.6, etc., and chlorine gas such as Cl.sub.2, BCl.sub.4, etc. may be used as the cleaning gas. Still further, not only a semiconductor wafer, but also a liquid crystal display device, etc. may be used as the process target.

Further, application of the present invention is not limited to a parallel-plate type. The present invention can be applied to other plasma processing apparatuses such as an ECR (Electron Cyclotron Resonance) type, an ICP (inductive Coupled Plasma) type, a helicon type, etc. Further, the present invention can bc applied not only to a plasma CVD apparatus, but also to other apparatuses utilizing plasma such as an etching apparatus, a sputtering apparatus, an annealing apparatus, etc.

As explained above, according to the present invention, efficient cleaning can be performed.

Various, embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2001-394282 filed on Dec. 26, 2001 and including specification, claims, drawings and summary. The disclosure of the above Japanese Patent Application is incorporated herein by reference in its entirety.

That is claimed is:

1. A plasma processing apparatus comprising:
a chamber;
a process gas line which supplies a predetermined process gas into said chamber;
a diffusion electrode to which high frequency electricity can be applied, and which includes: a diffusion path which is connected to said process gas line for diffusing the process gas introduced through said process gas line; and a plurality of gas holes which are connected to said diffusion path for supplying the process gas diffused by said diffusion path into said chamber;
a cleaning gas line which supplies a cleaning gas for cleaning the inside of said chamber into said chamber; and
a cleaning gas exhaustion line one end of which is connected to at least one of said process gas line and said diffusion path, the other end of which is connected to a gas exhaustion mechanism, and which exhausts the cleaning gas in said chamber.

2. The plasma processing apparatus according to claim 1, further comprising a process gas exhaustion line which exhausts the process gas introduced into said chamber through said process gas line,
wherein said process gas exhaustion line exhausts the process gas in said chamber via said gas exhaustion mechanism.

3. The plasma processing apparatus according to claim 2, wherein:
said chamber comprises a gas exhaustion port;
said process gas exhaustion line comprises a valve which is provided between said gas exhaustion mechanism and said gas exhaustion port;
the other end of said cleaning gas exhaustion line is connected between said valve of said process gas exhaustion line and said gas exhaustion mechanism; and
said gas exhaustion mechanism exhausts the cleaning gas in said chamber through said cleaning gas exhaustion line while said valve is closed.

4. The plasma processing apparatus according to claim 1,
wherein said cleaning gas line comprises a gas activation mechanism, and supplies the cleaning gas which is activated by said gas activation mechanism into said chamber.

5. The plasma processing apparatus according to claim 4,
wherein said gas activation mechanism generates plasma of the cleaning gas.

6. A plasma processing apparatus comprising:
a chamber;
a cleaning gas line which supplies a cleaning gas for cleaning the inside of said chamber into said chamber;
a cleaning gas inlet port which has an opening communicated with the inside of said chamber, and is connected to said cleaning gas line, the cleaning gas being introduced into said chamber through said opening; and
an opening and closing member which can open or close said cleaning gas inlet port.

7. The plasma processing apparatus according to claim 6, further comprising a cleaning gas inlet path which is connected to said cleaning gas line and said cleaning gas inlet port, and which introduces the cleaning gas from said cleaning gas line to said opening of said cleaning gas inlet port,
wherein said opening and closing member opens or closes said cleaning gas inlet port by opening or closing a route communicating said cleaning gas inlet path and said opening.

8. The plasma processing apparatus according to claim 6,
wherein said opening and closing member comprises a lid which can be fit into said opening, a supporting member which supports said lid, and a driving mechanism which is connected to said supporting member for driving said lid to move back and forth.

9. The plasma processing apparatus according to claim 8,
wherein a surface of said lid which is exposed in said chamber and an internal surface of said chamber constitute an almost same plane, when said lid is fit into said opening.

10. The plasma processing apparatus according to claim 8,
wherein said lid is set at a same electric potential as that of said chamber.

11. The plasma processing apparatus according to claim 8,
wherein:
said lid comprises a sealing member; and
said sealing member seals between said chamber and said lid airtightly, when said lid is fit into said opening.

12. The plasma processing apparatus according to claim 6,
wherein said cleaning gas line comprises a gas activation mechanism, and supplies the cleaning gas which is activated by said gas activation mechanism into said chamber.

13. The plasma processing apparatus according to claim 12,
wherein said gas activation mechanism generates plasma of the cleaning gas.

14. A plasma processing apparatus comprising: a chamber; a cleaning gas line which supplies a cleaning gas for cleaning the inside of said chamber; and a cleaning gas inlet port which is provided to said chamber for introducing the cleaning gas supplied from said cleaning gas line into said chamber,
wherein:
said cleaning gas inlet port is provided with a lid having a plurality of openings, and introduces the cleaning gas supplied from said cleaning gas line into said chamber through said plurality of openings; and
said plurality of openings are formed so that cleaning gas flows which pass through said respective openings may not interfere with each other.

15. The plasma processing apparatus according to claim 14,
wherein said cleaning gas line comprises a gas activation mechanism, and supplies the cleaning gas which is activated by said gas activation mechanism into said chamber.

16. The plasma processing apparatus according to claim 15,
wherein said gas activation mechanism generates plasma of the cleaning gas.

17. A method of cleaning a plasma processing apparatus for cleaning a plasma processing apparatus which comprises: a chamber; a process gas line which supplies a predetermined process gas into said chamber; and a diffusion electrode to which high frequency electricity can be applied, and which includes a diffusion path which is connected to said process gas line for diffusing the process gas introduced through said process gas line and a plurality of gas holes which arc connected to said diffusion path for supplying the process gas diffused by said diffusion path into said chamber, said method comprising:
an introducing step of introducing a cleaning gas into said chamber; and
a gas exhausting step of exhausting the cleaning gas introduced into said chamber out of said chamber through at least one of said process gas line and said diffusion path.

18. The method of cleaning a plasma processing apparatus according to claim 17,
wherein:
said plasma processing apparatus comprises a process gas exhaustion mechanism which exhausts the process gas introduced into said chamber from said process gas line; and
in said gas exhausting step, the cleaning gas introduced into said chamber is exhausted through said process gas exhaustion mechanism.

19. The method of cleaning a plasma processing apparatus according to claim 18,
wherein:
said plasma processing apparatus comprises a valve which is provided between said process gas exhaustion mechanism and a gas exhaustion port of said chamber, and a cleaning gas exhaustion line which is connected to a gas exhaustion side of said valve and exhausts the cleaning gas in said chamber; and
in said gas exhausting step, the cleaning gas in said chamber is exhausted through said cleaning gas exhaustion line with said valve closed.

20. The method of cleaning a plasma processing apparatus according to claim 17,
wherein said introducing step includes an activating step of activating the cleaning gas.

21. The method of cleaning a plasma processing apparatus according to claim 20,
wherein in said activating step, plasma of the cleaning gas is generated.

22. A method of cleaning a plasma processing apparatus for cleaning a plasma processing apparatus which comprises: a chamber; a cleaning gas line which supplies a cleaning gas for cleaning the inside of said chamber into said chamber; a cleaning gas inlet port which has an opening communicated with the inside of said chamber, and is connected to said cleaning gas line, the cleaning gas being introduced into said chamber through said opening; and an opening and closing member which can open or close said cleaning gas inlet port,
wherein plasma processing is performed while said cleaning gas inlet port is closed by said opening and closing member, and cleaning is performed while said cleaning gas inlet port is opened by said opening and closing member.
